(19) United States
(12) Patent Application Publication
(10) Pub. No.: US 2002/0070412 A1
(43) Pub. Date: Jun. 13, 2002

(54) Integrated semiconductor device having a lateral power element

(76) Inventors: Heinz Mitlehner, Uttenreuth (DE); Dethard Peters, Hochstadt (DE); Benno Weis, Hemhofen (DE)

Correspondence Address: LERNER AND GREENBERG, P.A., Post Office Box 2480, Hollywood, FL, 33022-2480, US

(21) Appl. No.: 09/968,660

(22) Filed: Oct. 1, 2001

Related U.S. Application Data
(63) Continuation of application No. PCT/DE00/00812, filed on Mar. 16, 2000.

(30) Foreign Application Priority Data
Mar. 31, 1999 (DE) 199 14 803.1

(51) Int. Cl. H01L 31/062; H01L 29/76; H01L 31/113

(52) U.S. Cl. 257/401; 257/341

(57) ABSTRACT

A semiconductor device contains a lateral power element. The power element is provided within a semiconductor layer formed of a semiconductor material having an energy gap of at least 2 eV and is laterally bounded by a trench in the semiconductor layer. The semiconductor layer is provided on a substrate having a thermal conductivity greater than that of silicon and is electrically insulated from a substrate surface remote from the semiconductor layer. This results in an integratable semiconductor device having a high reverse voltage and a high switching frequency.

### CROSS REFERENCE TO RELATED APPLICATION

This application is a continuation of copending International Application No. PCT/DE00/00812, filed Mar. 16, 2000, which designated the United States.

### BACKGROUND OF THE INVENTION

1. Field of the Invention

The invention relates to a semiconductor device having at least one lateral power element.

A semiconductor device having a power element is currently used in a variety of embodiments inter alia in the field of power converter technology. With the aid of a power converter, electrical energy is converted in accordance with the requirements of a load to be supplied. A power converter is therefore simply also referred to as a converter. Other designations that are customary for special configurations are inverters or rectifiers. The semiconductor device respectively used for this purpose includes, depending on the specific requirement, as a switching power element, a gate turn-off thyristor (GTO thyristor), an insulated gate bipolar transistor (IGBT), a metal oxide semiconductor field-effect transistor (MOSFET) or a MOS-controlled thyristor (MCT).

Demands made of a power converter include a high reverse voltage, a high forward current, a high switching frequency, a low power loss (waste heat), a high reliability and also a low outlay for the construction and connection technology.

The most compact form of a power converter is achieved with an integrated construction in which all the power elements and all the further components such as e.g. freewheeling diodes, drive devices, monitoring and protective devices are provided on a single substrate.

A power converter of this type integrated in silicon (Si) is described in “MOS-Bauelemente in der Leistungselektronik” [MOS components in power electronics], F. Schörlin, 1997, pages 182 to 187. Such a power converter is also known by the term “smart power.” In addition to the actual power flow control realized by the power elements, various digital and analog small-signal functions such as protection against overtemperature, overload, overvoltage, short circuit, polarity reversal and protection of the input side are also concomitantly integrated in the silicon power converter described. The semiconductor device contains a plurality of MOSFETs as power elements. On account of the otherwise very high on resistance, the large area requirement and the high static losses, the integrated silicon MOSFETs are usually configured only for a maximum permissible reverse voltage in the range between 5 V and 50 V.

“Smart Power ICs”, B. Murari et al., 1996, page 58, explains in this respect that the resistance in the on state of a MOSFET realized in silicon increases greatly with rising reverse voltage. This is caused, inter alia, by the long drift zone required in silicon in the case of a high reverse voltage.

A silicon-based integrated power converter configured for a reverse voltage of up to 500 or up to 600 V is described in “A 500 V 1 A 1-Chip Inverter IC on SOI Wafer”, K. Endo et al., Power Conversion, May 1998, Proceedings, pages 145 to 150, or else in “Smart Power ICs”, B. Murari et al., 1996, pages 163 to 169. Instead of the MOSFETs, however, this semiconductor device then includes lateral IGBTs, which permit a higher forward current than a MOSFET of comparable size and reverse voltage strength. However, due to the stored charge effect, the switching speed of this power converter is limited to a frequency of the order of magnitude of 20 kHz. The larger stored charge compared with the conditions in a MOSFET can in this case be attributed to the bipolar mechanism manifested in an IGBT. Moreover, on account of the material properties of silicon, the concomitantly integrated freewheeling diode also effects a relatively high storage of charge carriers at the pn junction of the freewheeling diode.

In order to circumvent the limiting of the switching speed that is concomitantly caused by the silicon freewheeling diode, Published, Non-Prosecuted German Patent Applciation No. DE 196 38 620 A1 discloses a non-integrated power converter using hybrid construction technology. In this case, a fast-switching Schottky diode made of silicon carbide (SiC) and having a high blocking capability is used as a freewheeling diode. As a result, although the switching capacity of the freewheeling diode itself is improved, on the other hand a loss of switching speed again results on account of the wiring of the individual elements that is now necessary. An external wiring is always associated with parasitic inductances and capacitances. Furthermore, a hybrid construction requires more space than an integrated solution and, moreover, is more complicated to realize.

Moreover, the paper “High-Voltage (2.6 kV) Lateral DMOSFETs in 4H-SiC”, J. Spitz et al., Materials Science Forum, Vol. 264 to 268, 1998, pages 1005 to 1008 describes a lateral power MOSFET based on 4H-SiC. In this case, the MOSFET disclosed is distinguished by a particularly high reverse voltage strength. A reverse voltage of about 2.6 kV is specified for room temperature. In the on state, however, the MOSFET has a high resistance, as a result of which the power loss rises. Moreover, the lateral MOSFET disclosed is not suitable for integration.

U.S. Pat. No. 5,710,455 discloses a further lateral SiC-MOSFET for voltages between 600 V and 1200 V. The lateral insulation of the lateral SiC-MOSFET is effected through the use of a pn junction. If the temperature of the lateral SiC-MOSFET disclosed then rises, for example on account of a high forward current, an undesirable high leakage current can occur at the pn junction used for lateral insulation. Furthermore, the stored charge zone of the pn junction, the zone constituting a relatively high capacitance, has to be subjected to charge reversal in each switching cycle. This has the result of limiting the switching speed that can be achieved.

### SUMMARY OF THE INVENTION

It is accordingly an object of the invention to provide an integratable semiconductor device which overcomes the above-mentioned disadvantages of the heretofore-known semiconductor devices of this general type and which is suitable even for a reverse voltage of more than 600 V and a switching frequency of more than 20 kHz. Moreover, the semiconductor device is intended to have a small space requirement in order to facilitate the integration.

With the foregoing and other objects in view there is provided, in accordance with the invention, a semiconductor device, including:

a substrate having a given thermal conductivity greater than a thermal conductivity of silicon;

a semiconductor layer disposed on the substrate, the semiconductor layer being formed of a semiconductor material having an energy gap of at least 2 eV;

the substrate having a substrate surface remote from the semiconductor layer, and the semiconductor layer being electrically insulated from the substrate surface;

a lateral power element disposed in the semiconductor layer, the lateral power component being configured as a normally off MOSFET having an inverse diode as an integral component, the inverse diode being configured to operate as a freewheeling diode; and the semiconductor layer having a trench formed therein, and the lateral power element being laterally bounded at least partly by the trench formed in the semiconductor layer.

In the semiconductor device according to the invention, at least one lateral power element is provided within a semiconductor layer made of a semiconductor material having an energy gap of at least 2 eV and is laterally bounded at least partly by a trench in the semiconductor layer. The semiconductor layer is provided on a substrate having a thermal conductivity greater than that of silicon and is electrically insulated from a substrate surface remote from the semiconductor layer.

In this case, the invention is based on the insight that a semiconductor device can still be realized using integrated technology even when there is a demand for a high reverse voltage (≧600 V) and a high switching frequency (≧20 kHz). In order to ensure a high reverse voltage, it is particularly advantageous in this case to use a semiconductor material having a high energy gap, in particular having an energy gap of at least 2 eV. This semiconductor material then inherently has a significantly higher dielectric strength than the silicon used hitherto for an integrated construction.

Due to the higher energy gap and the associated higher breakdown field strength, it is possible, moreover, for the geometrical dimensioning to be chosen to be smaller than in a comparable silicon semiconductor device. This then in turn accommodates integration.

It was furthermore recognized that an integratable silicon-based semiconductor device including e.g. a MOSFET as power element is also limited to a maximum permissible reverse voltage of about 50 V because only a comparatively small amount of heat can be dissipated in silicon. This limited thermal conductivity also limits the maximum permissible voltage since the on-state losses and hence the amount of heat to be dissipated rise with increasing voltage. By contrast, the substrate of the semiconductor device according to the invention advantageously includes a material having a thermal conductivity higher than that of silicon. As a result, the heat can then be reliably dissipated via the substrate.

With regard to integrability, it is particularly favorable if the semiconductor device includes a power element having a lateral structure. In a lateral power element, the forward current flows essentially parallel to a direction running within the substrate surface, that is to say in the lateral direction. In contrast to this, in a semiconductor device or a power element having a vertical structure, the current flows essentially perpendicularly to the substrate surface, that is to say in the vertical direction. Electrical terminals via which the current is conducted into a vertical semiconductor device and out of the latter again are then situated on sides of the semiconductor device that are remote from one another. By contrast, these terminals are located on the same side of the semiconductor device in the case of a lateral structure. This is favorable for integration since through-plating through the substrate is obviated.

If the active semiconductor layer within which the lateral power element is provided is electrically insulated from the substrate surface remote from the semiconductor layer, then this substrate surface can be mechanically connected, without additional safety precautions, to another body, for example a housing wall or a heat sink. The electrical insulation ensures that there is not an impermissibly high voltage on the adjacent body.

The trench in the active semiconductor layer is provided for lateral electrical insulation of the lateral power element. The trench laterally bounds the power element. This results not only in the vertically acting substrate insulation but also in an additional electrical insulation with a lateral direction of action. By virtue of this insulation of the power element on all sides, it is then also possible to permit different potentials at different regions on the substrate. Mutual influencing or even a flashover between such regions having a different potential is reliably prevented by the above-described insulation in the lateral and vertical direction. This is a further important property with regard to integrability. Moreover, compared with the lateral insulation through the use of a pn junction as used in the prior art, a trench has a significantly lower capacitance, so that a higher switching frequency is possible.

In one preferred embodiment, for the semiconductor layer within which the lateral power element is provided, monocrystalline silicon carbide (SiC), gallium nitride (GaN) or diamond is provided as the semiconducting material. In this case, the semiconductor layer contains such a material or it is formed of such a material. All the semiconductors mentioned have a very high energy gap and are thus highly suitable for a semiconductor device, since a high reverse voltage strength constitutes one of the main requirements made of the semiconductor device.

A preferred embodiment in which monocrystalline SiC of the 6H or 15R polytype is provided for the active semiconductor layer is particularly advantageous, in which case the semiconductor layer can again only contain such a polytype or else completely be formed of such a polytype. The two polytypes mentioned have both high lateral mobility and high inversion channel mobility. In the case of a power element configured as a lateral MOSFET, the forward resistance in a lateral drift region is then reduced e.g. on account of the first-mentioned mobility and the resistance in a channel region is reduced on account of the second-mentioned mobility. These mobilities are significantly higher in 6H— and 15R-SiC than in other polytypes of SiC, in particular including the 4H polytype. A high charge carrier mobility also makes it possible to achieve a high switching speed for the semiconductor device. In principle, however, all other SiC polytypes, such as e.g. also 3C-SiC, are also suitable. 4H-SiC with a correspondingly improved interface conductivity and/or improved inversion channel mobility is also a suitable material, in principle, for the semiconductor layer.

In one advantageous variant, the substrate contains silicon carbide or aluminum nitride (AlN). However, it is also possible for the substrate to include only SiC or AlN. SiC has a thermal conductivity of 2.3 to 4.9 Wcm⁻¹K⁻¹, depending on the polytype. By contrast, the thermal conductivity of silicon is only 1.5 Wcm⁻¹K⁻¹. This results in a significantly improved heat transfer through the substrate if SiC, rather than Si, is used as the substrate material. In this case, the combination of an SiC semiconductor layer and an SiC substrate is particularly advantageous with regard to the application of the active semiconductor layer e.g. through the use of an epitaxy process. In the case of a GaN semiconductor layer, by contrast, AlN is better suited as the substrate material since the respective lattice constants of GaN and AlN differ only slightly from one another.

An embodiment in which a substrate made of semi-insulating silicon carbide is provided is advantageous. In this case, the substrate can completely be formed of semi-insulating SiC or else only contain semi-insulating SiC, e.g. in a whole-area layer. A material is generally referred to as semi-insulating when its resistivity lies between about 10⁵ Ωcm and about 10¹⁰ Ωcm. Accordingly, it would then be referred to as insulating above a resistivity of about 10¹³ Ωcm. In the present case, semi-insulating behavior is entirely sufficient for the required degree of electrical isolation here between the semiconductor layer and the substrate surface remote from the semiconductor layer. In addition to the good thermal conductivity that is inherent to SiC anyway, semi-insulating SiC thus also affords the demanded electrical insulation in the vertical direction.

In a further advantageous embodiment, this electrical insulation is ensured by a pn junction provided between the active semiconductor layer and the substrate. A weakly p- or n-conducting semiconductor material can then be used for the substrate. An additional semiconducting intermediate layer having a doping higher than that of the substrate is then advantageously provided on the substrate surface facing the semiconductor layer. The electrically insulating pn junction is formed between this intermediate layer and the active semiconductor layer provided thereon.

In general, a semiconductor device realized in SiC affords the advantage of a very high thermal conductivity both in the vertical direction via the SiC substrate and in the lateral direction via the SiC semiconductor layer. By contrast, the SiO₂ layers or regions that are often used for vertical and lateral insulation in a semiconductor device realized in silicon have a significantly poorer thermal conductivity. Therefore, an SiC semiconductor device can also carry a significantly higher current than its silicon counterpart. The heat loss caused by the current can be dissipated more easily via the SiC.

In another advantageous embodiment, the trench is at least so deep that it completely severs the active semiconductor layer. The lateral electrical insulation is then particularly effective. The thickness of the active semiconductor layer usually lies between about 2 and 10 μm. In this case, the thickness chosen essentially depends on the forward current demanded. The lateral electrical insulation is improved further if a dielectric insulation layer, for example made of an oxide or a polyimide, is provided at edges of the trench. The trench preferably runs as a closed ring around the lateral field-effect transistor.

In a further embodiment, in which the semiconductor device includes more than one lateral power element, the trench effects electrical insulation of a power element from an adjacent power element. This possibility for insulation of components provided adjacent to one another on a single substrate is of interest particularly for integration.

A further refinement provides an interruption of the trench between two adjacent power elements, for example between two adjacent lateral field-effect transistors. As a result, an electrical connection between these two adjacent lateral field-effect transistors can be produced in a simple manner. Depending on the interconnection of the individual components of the semiconductor device, it is thus readily possible to provide an electrical connection or else an electrical insulation.

In the context of another preferred embodiment, the power element is configured as a transistor, in particular as a field-effect transistor (FET) or as an IGBT, as a diode, in particular a pn or Schottky diode, or as a thyristor. In this case, preferred forms of the field-effect transistor are a JFET (=junction FET), a MOSFET or a MESFET (metal semiconductor FET), the use of a MOSFET being particularly advantageous. For the case where the power element mentioned is switchable, the semiconductor device in the associated embodiment then constitutes a semiconductor switch.

The use of a MOSFET is particularly advantageous. The high energy gap of the semiconductor material used makes it possible to use a field-effect transistor as a power element even at the high reverse voltages demanded. The IGBT used at a reverse voltage of a few 100 V in silicon technology is then unnecessary. As a result, however, the limiting of the switching speed that is caused in the IGBT as a result of the bipolar mechanism used is obviated as well.

An embodiment in which the MOSFET has an inverse diode as an integral component is particularly favorable. This inverse diode can then advantageously be used as a freewheeling diode. This reduces the space requirement since a separate freewheeling diode does not occupy space on the substrate. Moreover, the omission of the speed-limiting wiring of a separate freewheeling diode enables a higher switching frequency.

Furthermore, a MOSFET has a very low forward resistivity and, in contrast to a different power switching element such as an IGBT, a GTO or a thyristor, does not have a loss-causing threshold voltage in the on state.

Two further preferred embodiments provide interconnection of four or six lateral field-effect transistors to form a two-phase or three-phase converter, respectively. A normally off power switching element, in particular a normally off MOSFET, is especially suitable for use in a converter of this type. In both embodiments, the converter is in each case integrated on a single substrate. Moreover, it has a comparatively low number of individual components since the lateral field-effect transistors, through the use of their inverse diodes, in each case also fulfill the function of freewheeling diodes which is required for a converter. In this case, the converter may be configured for a reverse voltage of 600 V, 1000 V, 1200 V or 1800 V. The switching frequency is as much as 100 kHz, for example. However, a higher reverse voltage and also a higher switching frequency, e.g. in the GHz range, are equally possible. In particular, the switching frequency can be chosen to be so high that the acoustic noises generated during the switching operation lie in a frequency range which is no longer perceived by the human ear. In addition, the high switching frequency enables very flexible use of the integrated converter.

Another advantageous refinement is one in which, in addition to the power element, at least another further component which realizes a small-signal function is situated on the substrate. In particular, this further component makes it possible for a drive function or a monitoring function for the power element or for a converter to be concomitantly integrated on the substrate.

Other features which are considered as characteristic for the invention are set forth in the appended claims.

Although the invention is illustrated and described herein as embodied in an integrated semiconductor device having a lateral power element, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings, in which some elements are only schematically shown and which are not true to scale in order to better illustrate the elements.

### BRIEF DESCRIPTION OF THE DRAWINGS

FIG. 1 is a diagrammatic, partial sectional view of a first exemplary embodiment of a semiconductor device according to the invention having a lateral MOSFET;

FIG. 2 is a diagrammatic, partial sectional view of a second exemplary embodiment of a semiconductor device according to the invention having a lateral MOSFET;

FIG. 3 is a diagrammatic plan view of the exemplary embodiments of the semiconductor device from FIGS. 1 and 2;

FIG. 4 is a circuit diagram of a two-phase converter having four integrated MOSFETs;

FIG. 5 is a circuit diagram of a three-phase converter having six integrated MOSFETs; and

FIG. 6 is a plan view of the three-phase converter from FIG. 5.

### DESCRIPTION OF THE PREFERRED EMBODIMENTS

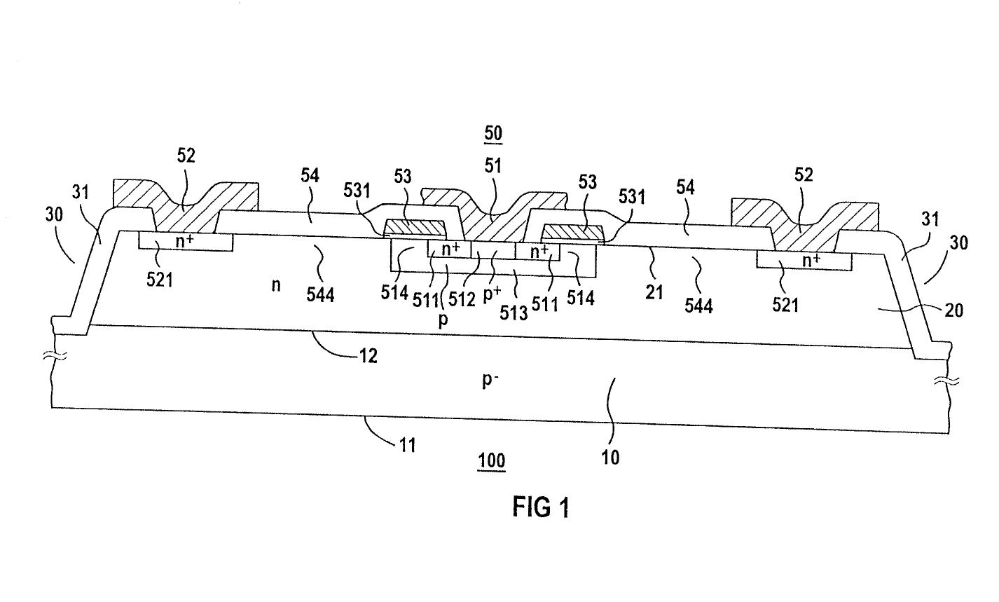

Referring now to the figures of the drawings in detail, in which corresponding elements are identified with the same reference symbols, and first, particularly, to FIG. 1 thereof, there is shown a semiconductor device 100 having a lateral MOSFET 50 as a power element. The semiconductor device 100 contains a semi-insulating SiC substrate 10 having a first and a second substrate surface 11 and 12, respectively. An epitaxially grown, weakly n-conducting semiconductor layer 20 made of monocrystalline SiC is provided on the second substrate surface 12. The active semiconductor layer 20 has a basic doping of about 1.3·10¹⁶ cm⁻³ and typically has a thickness of 5 μm.

The semi-insulating behavior of the substrate 10 ensures that the semiconductor layer 20 is electrically insulated from the first substrate surface 11 in a manner that is entirely sufficient for the present application.

The lateral MOSFET 50 is provided within the semiconductor layer 20. In this case, it adjoins a main surface 21 of the semiconductor layer 20, the main surface being remote from the second substrate surface 12. The construction and the method of operation of the lateral MOSFET 50 will be described in more detail below.

Two highly n-conducting drain contact regions 521 are spaced apart from a p-conducting base region 513 by a drift region 544 located within the semiconductor layer 20. Situated within the base region 513 are two highly n-conducting source contact regions 511, between which a heavily p-doped base contact region 512 is provided.

The n-conducting regions are in this case fabricated by ion implantation of nitrogen, and the p-conducting regions are fabricated by ion implantation of boron or aluminum.

A metallic drain electrode 52 makes ohmic contact with the drain contact regions 521. Ohmic contact is made with the source contact regions 511 and the base contact region 512 by a common, likewise metallic source electrode 51. The source contact regions 511 and the base contact region 512 are thus electrically short-circuited.

Between the two source contact regions 511 and the drift regions 544, respective channel regions 514 are situated within the base region 513, the doping concentration of which channel regions is about 1.3 10¹⁷ cm⁻³. An electric current fed into the lateral MOSFET 50 via the drain electrodes 52 and passed out again via the source electrode 51 can be controlled by targeted resistance influencing within the channel regions 514.

Therefore, for the purpose of power-free control, gate electrodes 53 are provided in an electrically insulated manner above the respective channel regions 514 to be controlled. A gate insulation layer 531, which is applied to the main surface 21 between the channel regions 514 and the gate electrodes 53, ensures the required electrical insulation. A material that is especially suitable for this gate insulation layer 531 is thermal silicon dioxide (SiO₂). The gate electrodes 53 include polysilicon, for example.

The drain electrodes 52, the source electrode 51 and also the gate electrodes 53 are electrically insulated from one another by a first dielectric insulation layer 54 applied on the main surface 21. This insulation layer 54 includes an oxide layer which is thick compared with the gate insulation layer 531. The oxide layer contains e.g. SiO₂, which can be fabricated by thermal oxidation of polysilicon or else in a simple manner through the use of a CVD (chemical vapor deposition) or a plasma deposition method. However, a different dielectric material, such as e.g. polyimide, is equally highly suitable for the insulation layer 54.

The lateral MOSFET 50 illustrated in FIG. 1 is configured for a reverse voltage of up to 1200 V and in this case has a width of only about 40 μm. By contrast, a comparable Si-MOSFET would have a width of 220 μm. In SiC, the semiconductor device 100 can thus be realized with a significantly smaller space requirement. The drift region 544 has a length of about 10 μm and the channel region 514 has a length of about 1.5 μm.

6H-SiC is provided for the active semiconductor layer 20, a (0001) plane of the 6H-SiC single crystal essentially coinciding with the main surface 21. Any misorientation of the substrate 10 of 3°, for example, provided for the epitaxial growth of the semiconductor layer 20 is unimportant in this context. The [0001] crystal orientation is particularly advantageous in combination with the lateral structure illustrated in FIG. 1. Firstly, the channel mobility of 6H-SiC is significantly higher compared with that of the 4H polytype and, secondly, the lateral mobility of the 6H polytype exceeds the vertical mobility by the factor 4.8. However, since a current flow via the MOSFET 50 takes place precisely in the lateral direction, the result is thus a low forward resistance in the drift region 544. Overall, a total resistance of about 4.2 Ωmm², which is essentially determined by the channel region 514 and the drift region 544, thus results in the on state.

When there is an electric voltage present between the drain electrode 52 and the source electrode 51 in the forward direction, the channel regions 514 can be switched back and forth between an off state and an on state through the use of a corresponding potential at the gate electrodes 53. Since the lateral MOSFET 50 is a normally off switching element, the switch-over to the off state already takes place when there is a zero potential present at the gate electrode 53. In the off state, the lateral MOSFET 50 is able to block a voltage of up to 1200 V present between the drain electrodes 52 and the source electrode 51.

The path via the base contact region 512, the base region 513, the semiconductor layer 20 and the drain contact region 521 includes a pn junction polarized in the reverse direction of the MOSFET 50. The diode associated with this pn junction is also referred to as an inverse diode. It is an integral component of the lateral MOSFET 50 and can be switched on through the use of a voltage present between the drain electrode 52 and the source electrode 51 in the reverse direction. The threshold voltage of this inverse diode is about 3 V, a value typical of SiC.

The inverse diode can be incorporated in a particularly advantageous manner into the method of operation of the semiconductor device 100. By way of example, if the actual lateral MOSFET 50 is switched into the off state through a corresponding potential at the gate electrode 53 and if, at the same time, the external circuitry (not shown in FIG. 1) requires a current in the reverse direction via the semiconductor device 100, then this current can be passed via the abovementioned inverse diode. In this case, the current commutates from the actual lateral MOSFET 50 to the inverse diode. The inverse diode functions as a freewheeling diode in this case. Since, during the operation of the inverse diode, within the semiconductor layer 20, essentially the same drift region 544 is utilized as during the operation of the actual lateral MOSFET 50, the inverse diode can automatically also carry approximately the same current intensity as the actual lateral MOSFET 50. Compared with a separate construction of the MOSFET 50 and the freewheeling diode on the substrate 10, the integrated freewheeling diode results in a reduction of the required substrate area by up to 75%. This corresponds to a reduction of the extent in an arbitrary lateral direction by a factor of up to 2.

Moreover, the integral inverse diode also fulfills the requirements made of a freewheeling diode operated e.g. in a converter circuit. Thus, only a small stored charge is built up in reverse operation, i.e. when the inverse diode is operated in the forward direction. This stored charge is rapidly reduced again in the event of transition to forward operation, the operating mode in which the lateral MOSFET 50 is operated as intended as a switch.

In this case, the small build-up of stored charge and the rapid reduction of stored charge are promoted in particular by the specific material properties of silicon carbide. Moreover, in the course of the ion implantation of the base region 513, additional defect sites can also be introduced in a targeted manner into the region of the pn junction of the inverse diode. These defect sites then serve as recombination centers and thus lead to a rapid reduction of injected charge carriers. Therefore, the semiconductor device 100 can be operated at a very high switching frequency up to the order of magnitude of at least 100 kHz.

The lateral MOSFET 50 additionally includes a parasitic bipolar transistor formed by the source contact region 511, the base region 513 and the semiconductor layer 20. In order to prevent this parasitic bipolar transistor from switching on, the region below the source contact region 511 may contain a higher p-type doping than the rest of the base contact region 513. This higher p-type doping is not illustrated in FIG. 1. Improving the latch-up strength is also an expression used in connection with this measure.

For the purpose of electrical insulation, a trench 30 is provided at the lateral edges of the lateral MOSFET 50. This trench 30 is so deep that it extends beyond the semiconductor layer 20 down into the semi-insulating SiC substrate 10. At its edges, the trench 30 is covered with a second dielectric insulation layer 31. The second dielectric insulation layer 31 may include SiO₂, like the first insulation layer 54. As an alternative to this, however, any other dielectric material, such as e.g. polyimide, is also possible here. Moreover, in accordance with another exemplary embodiment (now shown), it is also possible not to provide an insulation layer 31 at all at the edges of the trench 30.

The lateral MOSFET 50 illustrated in FIG. 1 thus fulfills all the preconditions for integration of a plurality of such lateral MOSFETs 50 on a single substrate 10. The electrical insulation from the first substrate surface 11 is ensured by the semi-insulating SiC substrate 10 itself. The electrical insulation from adjacent components, such as e.g. a further lateral MOSFET 50, is produced by the trench 30. On account of the high thermal conductivity of SiC the waste heat caused by losses is reliably dissipated via the substrate 10. This is still ensured even when a plurality of MOSFETs 50 that are connected in parallel e.g. in order to increase the current-carrying capacity are integrated on a substrate 10.

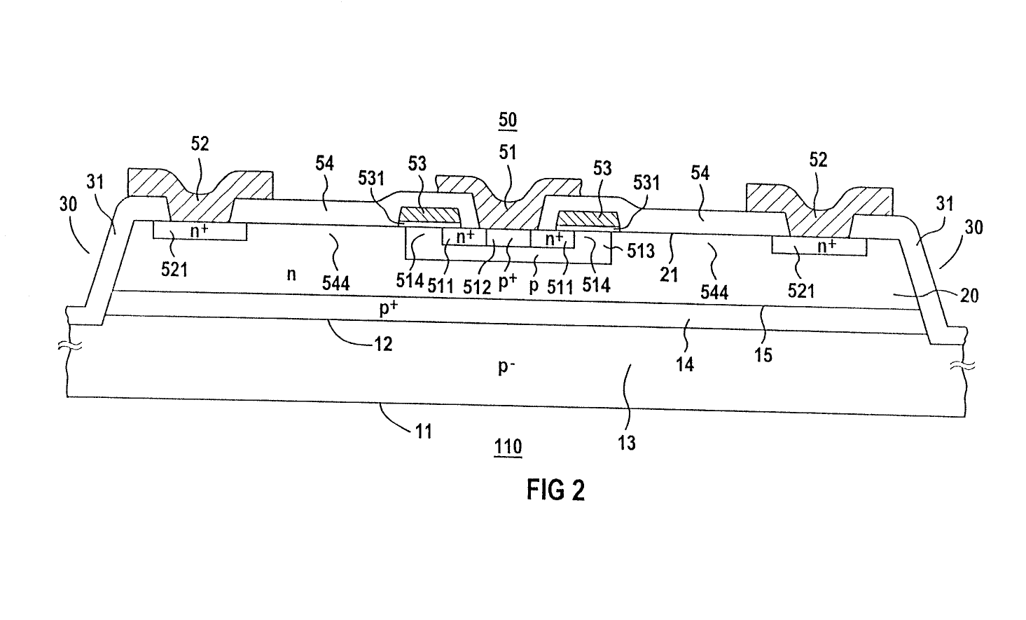

FIG. 2 illustrates a further exemplary embodiment of a semiconductor device 110 having a lateral MOSFET 50. In contrast to the exemplary embodiment of FIG. 1, the semiconductor device 110 of FIG. 2 does not contain a semi-insulating substrate 10, but rather a weakly p-doped substrate 13 made of 6H-SiC. In addition, a heavily p-doped intermediate layer 14 has been grown epitaxially on the second substrate surface 12. The likewise epitaxially grown semiconductor layer 20 is provided on the intermediate layer 14.

Between the semiconductor layer 20 and the intermediate layer 14, a whole-area pn junction 15 is produced on account of the opposite doping, and electrically insulates the semiconductor layer 20 from the first substrate surface 11. The lateral insulation of the lateral MOSFET 50 is effected analogously to the exemplary embodiment of FIG. 1 through the use of the trench 30, which in this case extends down into the weakly p-doped substrate 13.

The advantages mentioned in connection with FIG. 1 apply analogously to the exemplary embodiment of FIG. 2. In particular, the weakly p-doped substrate 13 also has a good thermal conductivity comparable to that of the semi-insulating SiC substrate 10.

It goes without saying that all the conduction types mentioned in connection with FIGS. 1 and 2 can also be replaced by the respective opposite conduction type.

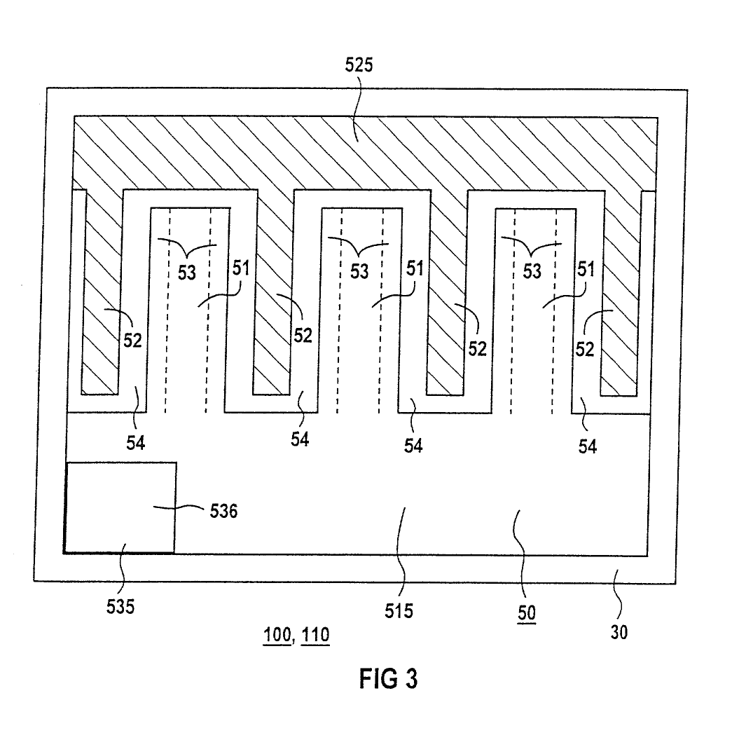

FIG. 3 illustrates a plan view of the semiconductor devices 100 and 110 of the exemplary embodiments from FIGS. 1 and 2. In order to increase the current-carrying capacity, the lateral MOSFET 50 can be modified to the effect that the structures shown in FIGS. 1 and 2 are multiply repeated in the lateral direction. Isolated from one another by drift regions 544, regions with drain contact regions 521 and regions which in each case include a base region 513, the associated base contact regions 512 and the associated source contact regions 511 then alternate with one another within the semiconductor layer 20. The mutually corresponding subregions of the individual regions are then respectively connected in parallel.

Such a construction is shown in FIG. 3. It includes two intermeshing comb-like structures. In this case, the tines of these comb-like structures respectively correspond to the drain electrodes 52 and the source electrodes 51. The first dielectric insulation layer 54 insulates the tines of the drain electrodes 52 from those of the source electrodes 51. The tines of the two comb-like structures are in each case electrically conductively connected to a web serving as a drain terminal region 525 and as a source terminal region 515, respectively.

Since the gate electrodes 53 are covered by the first dielectric insulation layer 54 provided above them and also by the source electrode, their respective profile is only illustrated by broken lines in FIG. 3. The individual gate electrodes 53 likewise merge with a common gate terminal region 535, which runs exactly below the source terminal region 515. Therefore, a cutout 536 is provided in the source terminal region 515 and makes the underlying gate terminal region 535 accessible for electrical contact-making.

In the exemplary embodiment of FIG. 3, the entire semiconductor device 100 or 110 is electrically insulated in the lateral direction by a trench 30 running all around the semiconductor device 100 or 110. On those sides of the trench 30 which are remote from the semiconductor device 100 or 110, it is possible to provide further components on the same substrate 10 or 13, respectively. These components are then electrically insulated from the semiconductor device 100 or 110.

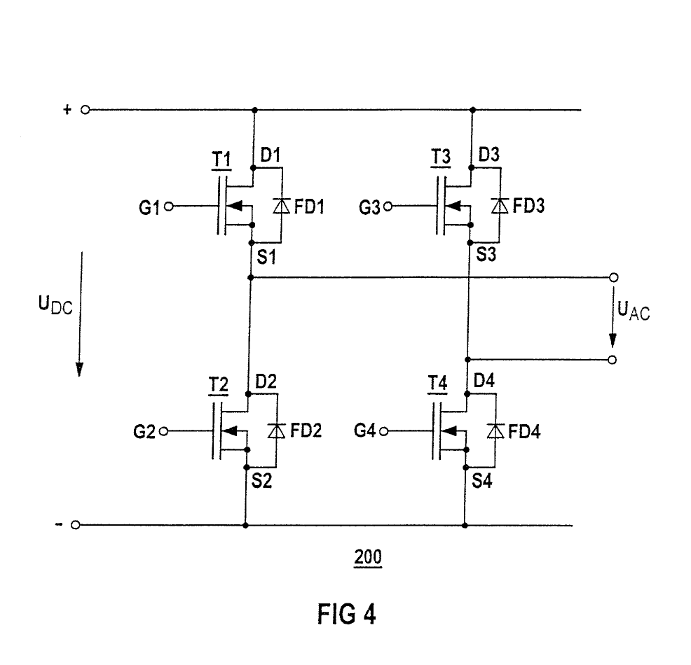

FIG. 4 illustrates a semiconductor device in the form of an integrated two-phase converter 200, which includes an interconnection, known per se, of a total of four MOSFETs T1 . . . T4. The MOSFETs T1 . . . T4 each have three electrical terminals, which are referred to as the drain terminal D1 . . . D4, source terminal S1 . . . S4 and gate terminal G1 . . . G4. In this case, the drain terminal D1 . . . D4, source terminal S1 . . . S4 and gate terminal G1 . . . G4 respectively correspond to the terminal regions mentioned in FIG. 3, drain terminal region 525, source terminal region 515 and gate terminal region 535, respectively.

A respective freewheeling diode FD1 . . . FD4 is reverse-connected in parallel with each MOSFET T1 . . . T4. In this case, the construction of the combination of the MOSFETs T1 to T4 and the freewheeling diodes FD1 . . . FD4 respectively corresponds to that described for the lateral MOSFET 50 in the previous figures. In particular the freewheeling diodes FD1 . . . FD4 constitute the integral inverse diode of the respective lateral MOSFET 50. All the MOSFETs T1 . . . T4 and freewheeling diodes FD1 . . . FD4 are provided on a single substrate 10 or 13, respectively. The converter 200 thus has a very compact configuration. At the same time, despite its small structural size, the integrated converter 200 is configured for a reverse voltage of 1200 V and a switching frequency of at least up to 100 kHz.

Moreover, through a common fabrication process for the individual MOSFETs T1 . . . T4, a practically identical layout is achieved, as a result of which the converter 200 operates in a balanced manner. Moreover, the converter 200 is suitable for a very high switching frequency since the integrated freewheeling diodes FD1 . . . FD4 firstly have a fast switching capacity on account of their low stored charge and, secondly, on account of the relatively high threshold voltage of 3 V, can even be completely switched off in a simple manner through correspondingly synchronous driving at the respective gate terminals G1 . . . G4.

With the aid of the converter 200, then, an AC voltage U_{AC} can be generated from a DC voltage U_{DC}, present at an input, given appropriate driving at the respective gate terminals G1 . . . G4. Through the use of the AC voltage U_{AC} present at an output, it is then possible, for example, to supply a two-phase electrical load (not illustrated) with electrical energy.

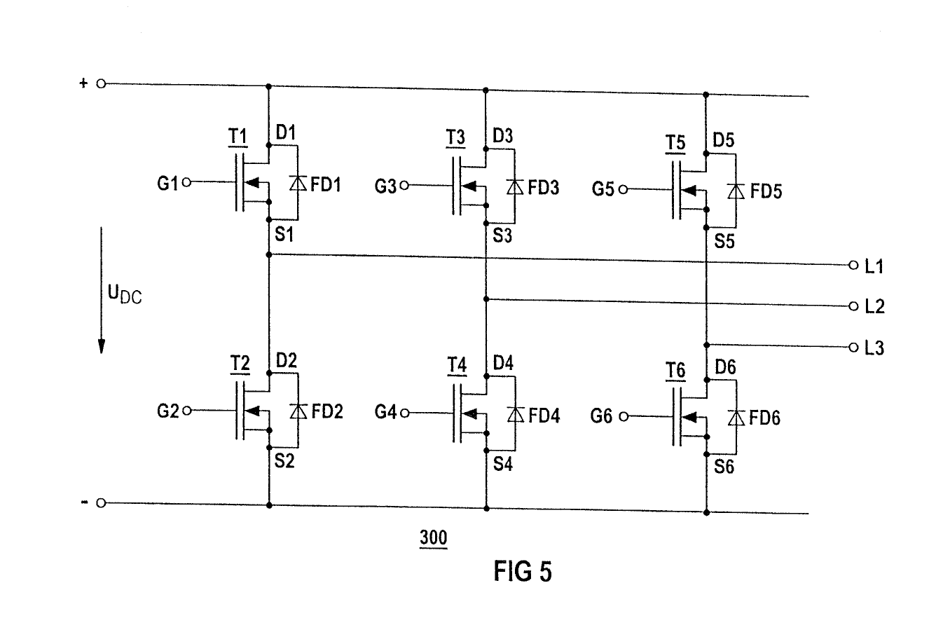

FIG. 5 illustrates an integrated three-phase converter 300, which converts the electrical DC voltage U_{DC} into a three-phase voltage which can be made available to a three-phase load via phase terminals L1, L2 and L3. The three-phase converter 300 contains a total of six MOSFETs T1 . . . T6 in an interconnection known per se. Each MOSFET T1 . . . T6 has a drain terminal D1 . . . D6, a source terminal S1 . . . S6 and a gate terminal G1 . . . G6 and also a reverse-connected parallel, integrated freewheeling diode FD1 . . . FD6. The converter 300 is again integrated on a single SiC substrate 10 or 13, respectively.

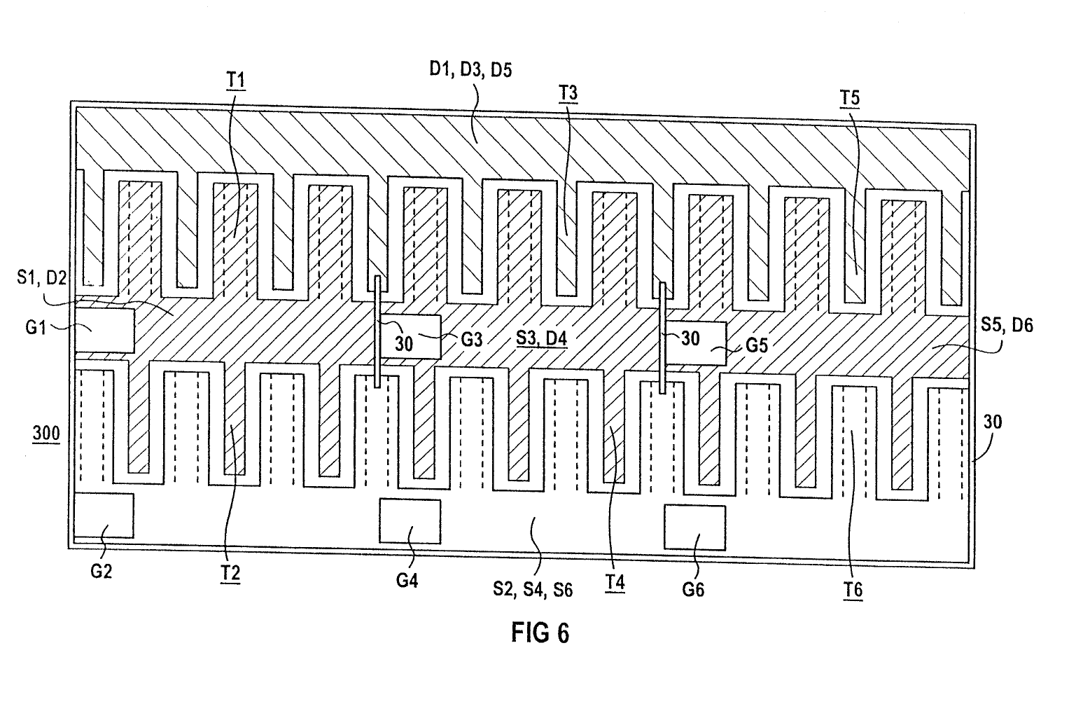

FIG. 6 illustrates a plan view of the integrated three-phase converter 300 from FIG. 5. In accordance with the interconnection of the individual MOSFETs T1 . . . T6, terminal regions assigned to a plurality of MOSFETs T1 . . . T6 can be seen in FIG. 6. Since an electrical connection between the individual MOSFETs T1 . . . T6 is desired in this case, an insulating trench 30 is not provided in the region of these contact points. By contrast, the trench 30 only runs in the regions in which electrical insulation is necessary on the basis of the electrical method of operation and the circuit diagram in accordance with FIG. 5.

The small space requirement of the integrated three-phase converter 300 is clearly revealed in FIG. 6. The integrated three-phase converter 300 is also configured for a reverse voltage of 1200 V and a switching frequency of up to 100 kHz. However, both the two-phase converter 200 and the three-phase converter 300 can also be configured for a higher reverse voltage and a higher switching frequency.

Besides the power switching elements in the form of the MOSFETs T1 . . . T6, in addition at least one further component e.g. with a logic function can be concomitantly integrated on the common substrate 10 or 13, respectively, on a side of the trench 30 that is remote from the MOSFETs T1 . . . T6. By way of example, a function for affording protection against overtemperature or overload can be realized using SIC-CMOS technology in this component.

We claim:

1. A semiconductor device, comprising:
a substrate having a given thermal conductivity greater than a thermal conductivity of silicon;
a semiconductor layer disposed on said substrate, said semiconductor layer being formed of a semiconductor material having an energy gap of at least 2 eV;
said substrate having a substrate surface remote from said semiconductor layer, and said semiconductor layer being electrically insulated from said substrate surface;
a lateral power element disposed in said semiconductor layer, said lateral power component being configured as a normally off MOSFET having an inverse diode as an integral component, said inverse diode being configured to operate as a freewheeling diode; and
said semiconductor layer having a trench formed therein, said lateral power element being laterally bounded at least partly by said trench formed in said semiconductor layer.

2. The semiconductor device according to claim 1, wherein said semiconductor layer contains a material selected from the group consisting of silicon carbide, gallium nitride, and diamond.

3. The semiconductor device according to claim 1, wherein said semiconductor layer contains silicon carbide of a polytype selected from the group consisting of a 6H polytype and a 15R polytype.

4. The semiconductor device according to claim 1, wherein said substrate contains a material selected from the group consisting of silicon carbide and aluminum nitride.

5. The semiconductor device according to claim 1, wherein said substrate contains a semi-insulating silicon carbide.

6. The semiconductor device according to claim 1, including a pn junction located between said substrate and said semiconductor layer for providing an electrical insulation.

7. The semiconductor device according to claim 1, wherein said semiconductor layer has a given thickness, said trench has a given depth at least as large as said given thickness of said semiconductor layer.

8. The semiconductor device according to claim 1, wherein said trench completely surrounds said lateral power element.

9. The semiconductor device according to claim 1, including:
a further lateral power element disposed adjacent to said lateral power element; and
said trench electrically insulating said lateral power element and said further lateral power element from one another.

10. The semiconductor device according claim 1, including:
a further lateral power element disposed adjacent to said lateral power element;
said trench being disposed between said lateral power element and said further lateral power element; and
said semiconductor layer having a given region for providing an electrically conductive connection between said lateral power element and said further lateral power element, said given region of said semiconductor layer interrupting said trench.

11. The semiconductor device according to claim 1, including:
three further lateral power elements; and
said lateral power element and said three further lateral power elements being lateral field-effect transistors and being interconnected to form a two-phase converter.

12. The semiconductor device according to claim 1, including:
five further lateral power elements; and
said lateral power element and said five further lateral power elements being lateral field-effect transistors and being interconnected to form a three-phase converter.

13. The semiconductor device according to claim 1, including at least one component with a small-signal function, said at least one component being concomitantly integrated on said substrate.
